(19) United States
(12) Patent Application Publication
(10) Pub. No.: US 2020/0100397 A1
(43) Pub. Date: Mar. 26, 2020

(54) THERMAL COUPLING OF SURROUNDINGS SENSORS IN THE VEHICLE ROOF TO THE VEHICLE PASSENGER COMPARTMENT CLIMATE

(71) Applicant: Robert Bosch GmbH, Stuttgart (DE)

(72) Inventors: Mustafa Kamil, Leonberg (DE); Siegwart Bogatscher, Leonberg (DE)

(21) Appl. No.: 16/580,422

(22) Filed: Sep. 24, 2019

(30) Foreign Application Priority Data
Sep. 26, 2018 (DE) 102018216426.6-

(51) Int. Cl. H05K 7/20; G01S 7/481; H05K 5/02; G01D 11/24

(52) U.S. Cl. CPC H05K 7/20872; G01S 7/4813; G01D 11/245; H05K 7/20154; H05K 5/0213

(57) ABSTRACT

An assembly configured to operate a surroundings sensor in a roof area of a means of transportation includes a thermally conductive segment and a thermal interface that is configured to protrude into, and be thermally connected to a volume of, a passenger compartment of the means of transportation.

### CROSS-REFERENCE TO RELATED APPLICATIONS

The present application claims priority under 35 U.S.C. § 119 to DE 10 2018 216 426.6 filed in the Federal Republic of Germany on Sep. 26, 2018, the content of which is hereby incorporated by reference herein in its entirety.

### FIELD OF THE INVENTION

The present invention relates to an assembly for operating a surroundings sensor and to a means of transportation, the assembly being used to improve the heat dissipation.

### BACKGROUND

Based on their function, surroundings sensors are installed on or in an outer skin of a means of transportation. Depending on the type of the sensor, it can be advantageous or even necessary to install the sensor in a high installation position to enable the sensor a good all-round view. Surroundings sensors are thus preferably mounted on the roof of a means of transportation. This exposed position causes the surroundings sensors to be subjected to environmental conditions. With an accordingly suitable housing, it is possible to shield the surroundings sensors against many of these environmental conditions, such as dust and moisture. However, it is almost impossible to shield the surroundings sensors against thermal conditions, for example against direct solar radiation and the solar radiation reflected on the roof surface to the housing. Additionally, the sensor itself also emits inherent heat during operation, which means additional thermal impact. To protect the sensor against overheating, it is therefore necessary to ensure appropriate heat dissipation.

DE 10 2013 204808 A1 describes a vehicle, in particular a road or rail vehicle, including a vehicle roof and a receptacle mounted on the vehicle roof. The upper side of the receptacle is provided with at least one profile component, which includes at least one support section resting on the upper side of the receptacle. This profile component is used, on the one hand, as a sun screen for the receptacle by providing shade and, on the other hand, for heat emission to the ambient air.

### SUMMARY

According to a first aspect, the present invention relates to an assembly for a surroundings sensor. Surroundings sensors can be optical sensors, such as a LIDAR sensor, but also non-optical sensors and actuators. The sensor is connected to a thermally conducting segment in a thermally well-conducting manner. It is also possible that only portions of the sensor are connected to the thermally conducting segment in a thermally well-conducting manner. This is useful, in particular, for the portions that emit heat during operation of the sensor. In addition to the thermally conducting segment, the assembly includes a thermal interface. The thermal interface preferably has a combination of a large surface and a small overall volume, such as a cooling element can have, for example. The thermal interface is preferably configured in such a way that it protrudes into a passenger compartment of a means of transportation on or in whose outer skin the assembly is situated. The effectiveness of the thermal interface can be favored in that smaller openings are provided in the vehicle bottom and/or in the side wall of the vehicle, via which cool ambient air is able to flow into the passenger compartment. From here, the cool air can be guided in the direction of the surroundings sensors for cooling them. The air can be guided through an intermediate level in the roof area of the vehicle structure. The cool air can also be guided to the thermal interface in the process, which is thermally coupled to the thermally conductive segment. The air guidance can thus generate a chimney effect in which very warm air is able to escape from the vehicle passenger compartment to the surroundings, while cold air is resupplied from the vehicle bottom or the vehicle sides. For the passenger, excessively warm air is able to escape upwardly, while it is still sufficiently cool for the surroundings sensors to ensure their functional reliability. In other words, a vertical temperature gradient, which causes an air convection, is generated by the openings in the vehicle bottom or in the vehicle sides. A motor-driven convection is thus not necessary. It is possible that the thermal interface is connected to a volume of the passenger compartment of the means of transportation in a thermally well-conducting manner, and thus a thermal energy exchange is able to take place between the thermal interface and the volume.

According to an example embodiment of the assembly according to the present invention, the assembly is thermally insulated from an outer skin of the means of transportation. In this way, it can be prevented that, for example, thermal energy of the heated outer skin of the means of transportation penetrates into the assembly and thus negatively affects a heat dissipation capacity of the assembly.

According to an example embodiment of the assembly according to the present invention, at least the thermal interface of the assembly penetrates the outer skin of the means of transportation. In this way, the thermally conducting interface can be guided into the vehicle passenger compartment and connected there to the volume of the passenger compartment of the means of transportation in a thermally well-conducting manner.

According to an example embodiment of the assembly according to the present invention, it is permanently mechanically connected to the means of transportation and/or in a stationary manner. The mechanical connection can be established, for example, by a bonded joint, a welded joint, or a screwed joint. In addition, a sealing compound can be introduced into the connection between the assembly and the means of transportation, for example to establish and ensure a thermal insulation between the assembly and the means of transportation.

According to an example embodiment of the assembly according to the present invention, the thermally conducting segment can include a thermally well-conducting material. The thermally conducting segment can also include a heat exchanger tube, in particular a heat pipe, the thermal properties of the heat exchanger tube, such as a minimal operating temperature and/or a heat transfer capacity, preferably being adapted to an operating temperature range of the surroundings sensor.

According to an example embodiment of the assembly according to the present invention, the thermal interface can be situated in such a way that it protrudes into the air flow of a heating/air conditioning duct of the means of transportation and/or can be supplied with air from the heating/air conditioning duct. In this way, the emission of thermal energy from the thermal interface to the volume can be improved, which improves the cooling capacity of the assembly. A control, such as an automated setpoint/actual compensation of a predefined temperature in an air-conditioned passenger compartment of a means of transportation, can be carried out by a control unit or by other control techniques of an automatic climate control system.

While a control of the assembly according to the present invention can be regulated or controlled by the assembly's own sensor system and logic, an automated setpoint/actual value comparison can also be monitored by automatic climate control systems that are present anyhow in conventional vehicles or readily retrofittable. All actuators for controlling the influence on the functionality of the assembly according to the present invention can be activated thereby. In this way, the vehicle passenger compartment is used as an additional large thermal capacity for the surroundings sensors to be able to attenuate positive and negative temperature peaks of the assembly according to the present invention. This improves the availability and the durability of the assembly according to the present invention.

According to an example embodiment of the assembly according to the present invention, the assembly can include a receptacle for the surroundings sensor to mechanically connect it to the assembly. To be able to rotate the surroundings sensor during operation, the assembly can include a rotor. To drive the rotor, the assembly can include an electric motor. The rotor can include a thermally well-conducting material. The assembly can also include a mechanical interface for attachment in or on the means of transportation. The mechanical interface can include a thread, a flange, an attachment rail or the like. To be able to operate the surroundings sensor, the assembly can furthermore also include an electrical supply unit and/or a connection for data exchange. These connections can be designed as contact elements or as plug connectors, for example. To protect the assembly and/or the surroundings sensor against environmental conditions, the assembly can include a thermally conductive housing, the thermally conductive housing being configured in such a way that it is able to accommodate the surroundings sensor. The surroundings sensor is connected to the thermally conductive segment via a thermal connection. The thermal connection can include a thermally well-conducting material.

According to an example embodiment of the assembly according to the present invention, the surroundings sensor can be a LIDAR sensor, for example. Other optical and non-optical sensors can also be situated in the assembly.

According to a second aspect, the present invention relates to a means of transportation, which includes an assembly according to the first aspect. Possible means of transportation within the meaning of the present invention are, for example, automobiles, in particular passenger cars, trucks, airplanes, and/or ships.

According to an example embodiment of the second aspect, a headliner can be situated between the assembly and the passenger compartment of the means of transportation. The headliner is air permeable or provided with thermally conductive surface areas. In this way, the headliner can act as a thermal intermediate level and contribute to the spatial homogenization of temperature differences in the passenger compartment of the means of transportation. The thermal interface can be visually hidden by the headliner, so that a user of the means of transportation does not perceive the thermal interface. The thermal interface can also penetrate the headliner and thus protrude into the passenger compartment. To further improve the heat dissipation of the thermal interface, the air circulation in the passenger compartment of the means of transportation can be further improved by additional openings in a vehicle bottom and/or in side trim panels, so that a chimney effect is created in the passenger compartment of the means of transportation. Example embodiments of the present invention are described hereafter in greater detail with reference to the accompanying drawings.

### BRIEF DESCRIPTION OF THE DRAWING

FIG. 1 shows an assembly according to an example embodiment of the present invention.

FIG. 2 shows an assembly according to another example embodiment of the present invention.

FIG. 3 shows a vehicle according to an example embodiment of the present invention.

FIG. 4 shows an assembly according to another example embodiment of the present invention.

### DETAILED DESCRIPTION

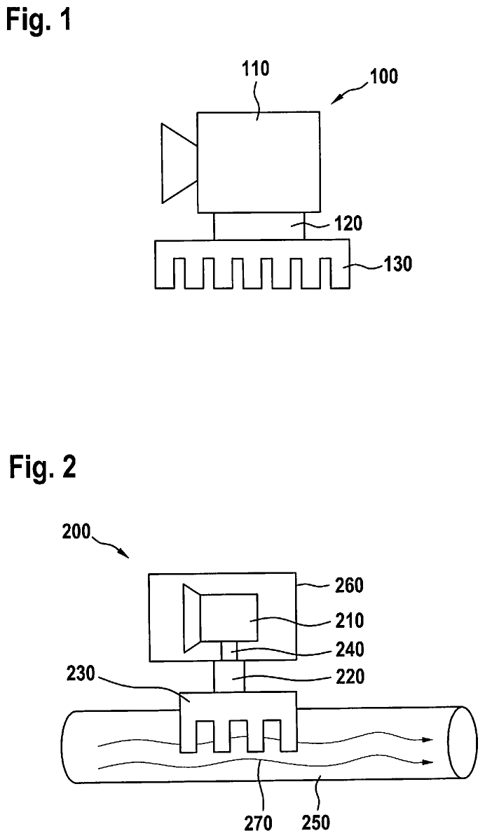

FIG. 1 shows assembly 100 according to an example embodiment of the present invention. The surroundings sensor is connected to thermally conductive segment 120 in a thermally well-conducting manner. Furthermore, thermally conductive segment 120 is connected to thermal interface 130 in a thermally well-conducting manner. Thermal interface 130 in this example embodiment is designed as a cooling element having a large surface and a small overall volume.

FIG. 2 shows another example of assembly 200. In this example embodiment, surroundings sensor 210 is situated in a thermally conductive housing 260. The outer sides of housing 260 can be surrounded by a thermal insulation. Surroundings sensor 210 is connected via a thermal connection 240 to an inner side of an outer wall of housing 260. This outer wall preferably includes a thermally well-conducting material to enable a good transfer or a good transport of thermal energy. Thermally conductive segment 220 is connected to an outer side of the outer wall of housing 260 in a thermally well-conducting manner. The thermal energy given off by surroundings sensor 210 can thus be transferred via thermal connection 240 and the outer wall of housing 260 to thermally conductive segment 220. It is also possible that thermally conductive segment 220 is connected directly to thermal connection 240 or directly to surroundings sensor 210 in a thermally well-conducting manner, and that thermally conductive segment 220 penetrates an outer wall of housing 260. Thermally conductive segment 220 is preferably thermally insulated from the outer wall of housing 260. Thermally conductive segment 220, in turn, is connected to thermal interface 230. Thermal interface 230 protrudes into a heating/air conditioning duct 250 and can thus be supplied with air 270 from the heating/air conditioning duct.

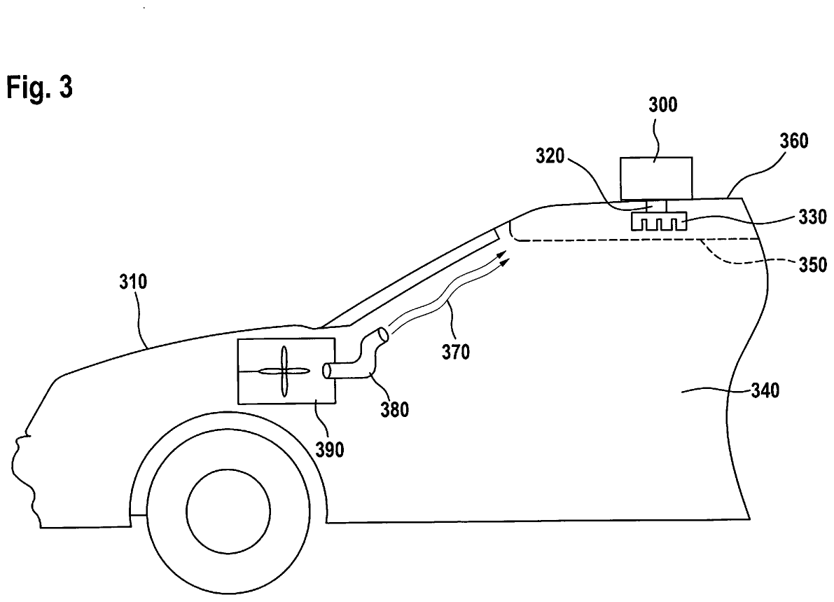

FIG. 3 shows assembly 300, thermally conductive segment 320 of assembly 300 penetrating an outer skin of a means of transportation 310 in roof area 360. In this way, thermal interface 330 of assembly 310 can be thermally connected to the volume of vehicle passenger compartment 340 and give off thermal energy to the volume of vehicle passenger compartment 340. Air conditioning system 390 of means of transportation 310 is also shown, which is able to supply thermal interface 330 of assembly 300 with air 370 via a heating/air conditioning duct 380. In this way, the dissipation of thermal energy from thermal interface 330 to the volume of vehicle passenger compartment 340 can be further improved. Air 370 from heating/air conditioning duct 380 can penetrate an air permeable headliner 350.

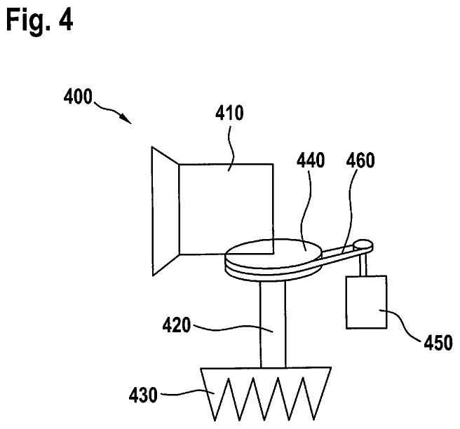

FIG. 4 shows an assembly according to a further example embodiment of the present invention. Surroundings sensor 410 is connected to a rotor 440 in a thermally well-conducting manner. In this way, it is made possible that surroundings sensor 410 can be rotated during operation. Rotor 440 is connected to thermally conductive segment 220 in a thermally well-conducting manner. Moreover, thermally conductive segment 420 is connected to the thermal interface in a thermally well-conducting manner. The rotor preferably includes a thermally well-conducting material. An electric motor 450 is situated in assembly 400 for driving rotor 440. In the present example, electric motor 450 can drive rotor 440 via a belt 460. It is also possible for rotor 440 to be driven directly, to be driven via mutually engaging gear wheels, or other drive forms known to those skilled in the art.

What is claimed is:

1. An assembly for operating a surroundings sensor situated in a roof area of a transportation device, the assembly comprising:
a thermally conductive segment; and
a thermal interface, wherein the thermal interface is configured to protrude into, and be thermally connected to a volume of, a passenger compartment of the transportation device.

2. The assembly of claim 1, wherein the assembly is thermally insulated from an outer skin of the transportation device.

3. The assembly of claim 1, wherein the assembly, except for the thermal interface, is thermally insulated from the transportation device.

4. The assembly of claim 1, wherein the assembly is configured for guidance of the thermal interface through an outer skin of the transportation device into the passenger compartment.

5. The assembly of claim 1, wherein the assembly is configured to be permanently mechanically connected to the transportation device.

6. The assembly of claim 1, wherein the thermally conductive segment includes thermally well-conducting material.

7. The assembly of claim 1, wherein the thermally conductive segment includes at least one heat pipe.

8. The assembly of claim 1, wherein the thermal interface is configured to be situated in a heating/air conditioning duct of the transportation device.

9. A vehicle comprising:
an assembly for operating a surroundings sensor situated in a roof area of the vehicle, the assembly including:
a thermally conductive segment; and
a thermal interface, wherein the thermal interface is protrudes into, and is thermally connected to a volume of, a passenger compartment of the vehicle.

10. The vehicle of claim 9, further comprising a headliner that is situated between the assembly and the passenger compartment and that is air permeable and/or is provided with thermally conductive surface areas.

11. The vehicle of claim 9, wherein the assembly includes a receptacle for the surroundings sensor.

12. The vehicle of claim 9, wherein the assembly includes a rotor configured to rotate the surroundings sensor during operation.

13. The vehicle of claim 12, wherein the assembly includes an electric motor configured to rotate the rotor.

14. The vehicle of claim 9, wherein the assembly includes a mechanical interface for attaching the assembly in or on the vehicle.

15. The vehicle of claim 9, wherein the assembly includes an electrical supply of the surroundings sensor.

16. The vehicle of claim 9, wherein the assembly includes a connection via which data is exchangeable with the surroundings sensor.

17. The vehicle of claim 9, wherein the assembly includes a thermally conductive housing configured to accommodate the surroundings sensor, the surroundings sensor being connected via a thermal connection to the thermal interface.

18. The vehicle of claim 9, wherein the surroundings sensor is a LIDAR sensor.
